(19) United States
(12) Patent Application Publication
(10) Pub. No.: US 2025/0054845 A1
(43) Pub. Date: Feb. 13, 2025

(54) LEAD FRAME, SEMICONDUCTOR DEVICE, AND LEAD FRAME MANUFACTURING METHOD

(71) Applicant: SHINKO ELECTRIC INDUSTRIES CO., LTD., Nagano-shi (JP)

(72) Inventors: Kentaro Kaneko, Nagano (JP); Muneaki Kure, Nagano (JP); Toru Maruyama, Nagano (JP)

(21) Appl. No.: 18/793,304

(22) Filed: Aug. 2, 2024

(30) Foreign Application Priority Data
Aug. 10, 2023 (JP) 2023-131267

(51) Int. Cl. H01L 23/495; H01L 23/00; H01L 23/31

(52) U.S. Cl. CPC H01L 23/49582; H01L 23/49548; H01L 23/3107; H01L 24/16; H01L 24/32; H01L 24/48; H01L 24/73; H01L 2224/16245; H01L 2224/32245; H01L 2224/48247; H01L 2224/73265

(57) ABSTRACT

A lead frame includes a lead, a connection portion, and a plating film. The lead includes an upper surface and a lower surface, and a width of the upper surface is larger than a width of the lower surface. The connection portion is arranged on the upper surface and serves as a connection portion for a semiconductor element. The plating film covers a surface of the lead.

### CROSS-REFERENCE TO RELATED APPLICATION

This application is based upon and claims the benefit of priority of the prior Japanese Patent Application No. 2023-131267, filed on Aug. 10, 2023, the entire contents of which are incorporated herein by reference.

### FIELD

The embodiment discussed herein is related to a lead frame, a semiconductor device, and a lead frame manufacturing method.

### BACKGROUND

In recent years, for example, a semiconductor device in which a semiconductor element, such as an Integrated Circuit (IC) chip, is mounted on a lead frame that is made of a metal is known. Specifically, for example, a semiconductor element is mounted on a planar-shaped die pad that is arranged in the center of a lead frame, and the semiconductor element is connected to a plurality of leads that are arranged around the die pad by, for example, wire bonding. Further, a semiconductor device may be formed by sealing the semiconductor element that is mounted on the lead frame by, for example, resin, such as epoxy resin.

In the semiconductor device as described above, an increase in the number of leads is accelerated, and a design is performed such that a width of the lead is decreased with an increase in the number of leads. With a decrease in the width of the lead, strength of the lead decreases, so that the lead may be deformed. In contrast, it may be possible to increase the strength of the lead by forming a protrusion on a side surface of the lead.
Patent Literature 1: Japanese Laid-open Patent Publication No. 2015-159273
Patent Literature 2: Japanese Laid-open Patent Publication No. 2017-228795

However, when the protrusion is formed on the side surface of the lead to increase the strength of the lead, a distance between the adjacent leads is not fully secured, so that a short circuit defect that is a contact between the adjacent leads may occur. In contrast, if any structure for increasing the strength of the lead is not provided, the lead is easily deformed, so that productivity of the lead frame is reduced.

### SUMMARY

According to an aspect of an embodiment, a lead frame includes a lead that includes an upper surface and a lower surface, the upper surface having a larger width than a width of the lower surface; a connection portion that is arranged on the upper surface and serves as a connection portion for a semiconductor element; and a plating film that covers a surface of the lead.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a specific example of an assembly of lead frames according to one embodiment;

FIG. 2 is a top view illustrating a structure of a lead frame according to one embodiment;

FIG. 3 is a bottom view illustrating the structure of the lead frame according to one embodiment;

FIG. 4 is a cross-sectional view taken along a line IV-IV in FIG. 2;

FIG. 5 is a diagram illustrating a cross-section perpendicular to a longitudinal direction of a lead;

FIG. 6 is a diagram illustrating a specific example of a surface of a plating film;

FIG. 7 is a diagram illustrating a specific example of a film thickness of the plating film;

FIG. 8 is a diagram illustrating a specific example of the film thickness of the plating film;

FIG. 9 is a diagram illustrating a specific example of a coating range of the plating film;

FIG. 10 is a diagram illustrating a specific example of the coating range of the plating film;

FIG. 11 is a flowchart illustrating a method of manufacturing the lead frame according to one embodiment;

FIG. 12 is a diagram illustrating a specific example of a structure of a metal plate;

FIG. 13 is a diagram illustrating a specific example of a DER lamination process;

FIG. 14 is a diagram illustrating a specific example of an exposure and development process;

FIG. 15 is a diagram illustrating a specific example of an etching process;

FIG. 16 is a diagram illustrating a specific example of a DFR stripping process;

FIG. 17 is a diagram illustrating a specific example of a plating film formation process;

FIG. 18 is a diagram illustrating a configuration example of a plating device that performs roughening copper plating;

FIG. 19 is a diagram illustrating a specific example of a resist application process;

FIG. 20 is a diagram illustrating a specific example of an exposure and development process;

FIG. 21 is a diagram illustrating a specific example of a plating process;

FIG. 22 is a diagram illustrating a specific example of a resist stripping process;

FIG. 23 is a flowchart illustrating a method of manufacturing a semiconductor device according to one embodiment;

FIG. 24 is a diagram illustrating a specific example of a semiconductor element mounting process;

FIG. 25 is a diagram illustrating a specific example of a wire bonding connection process;

FIG. 26 is a diagram illustrating a specific example of a molding process;

FIG. 27 is a diagram illustrating a specific example of a plating process;

FIG. 28 is a diagram illustrating a structure of a semiconductor device;

FIG. 29 is a cross-sectional view of a lead frame according to one modification of one embodiment; and

FIG. 30 is a diagram illustrating a structure of a semiconductor device that is manufactured by using the lead frame illustrated in FIG. 29.

### DESCRIPTION OF EMBODIMENT

Embodiments of a lead frame, a semiconductor device, and a lead frame manufacturing method disclosed in the present application will be described in detail below based on the drawings. The disclosed technology is not limited by the embodiments below.

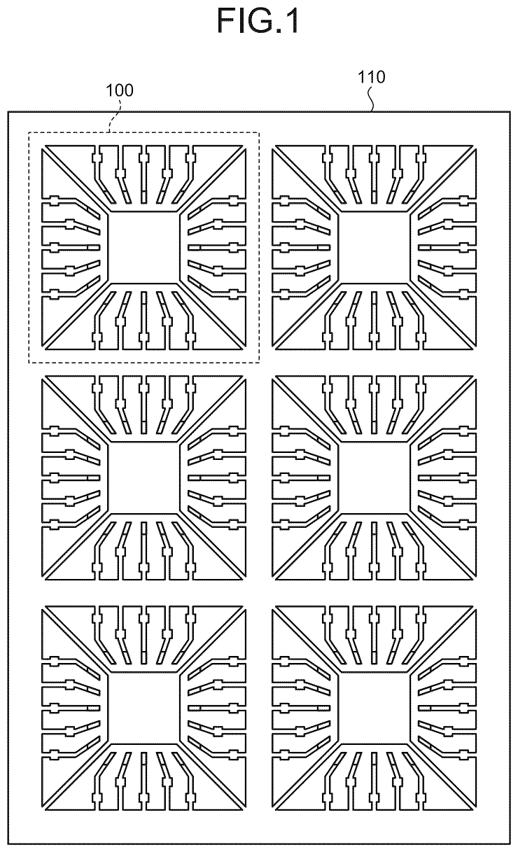

FIG. 1 is a diagram illustrating a specific example of an assembly of lead frames 100 according to one embodiment. As illustrated in FIG. 1, the lead frames 100 are manufactured as an assembly in which the plurality of lead frames 100 are connected to one another in a region that is enclosed by a frame body 110. In the example illustrated in FIG. 1, for example, etching, plating, and the like are performed by using a metal plate that is made of copper or a copper alloy, and the six lead frames 100 that are connected in a matrix of three rows and two columns are manufactured.

By manufacturing the assembly of the plurality of lead frames 100 as described above, it is possible to effectively manufacture the lead frames 100 and reduce a cost. The plurality of lead frames 100 that are manufactured as the assembly are divided into individual pieces, so that the lead frame 100 for mounting an electronic component, such as a semiconductor element, is obtained.

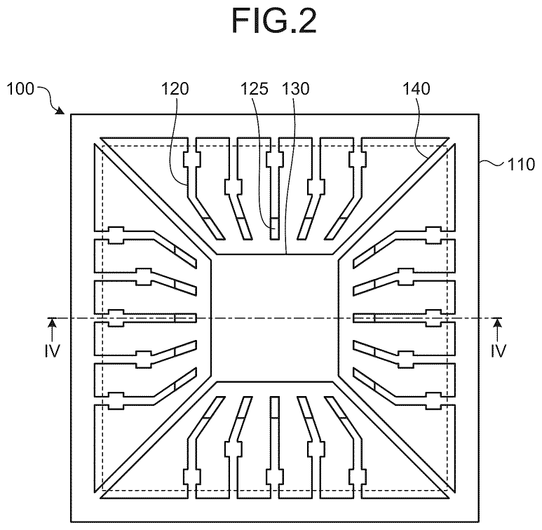

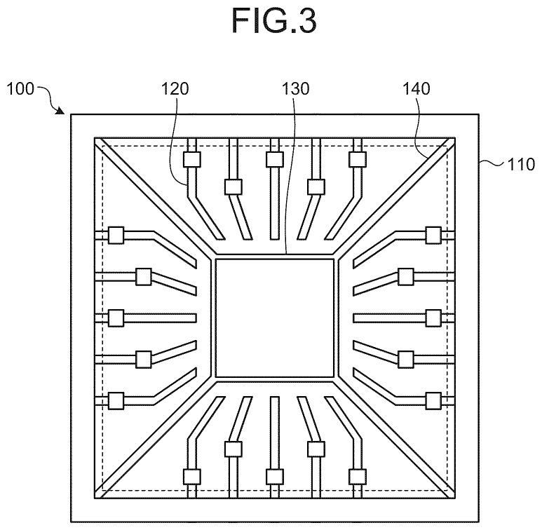

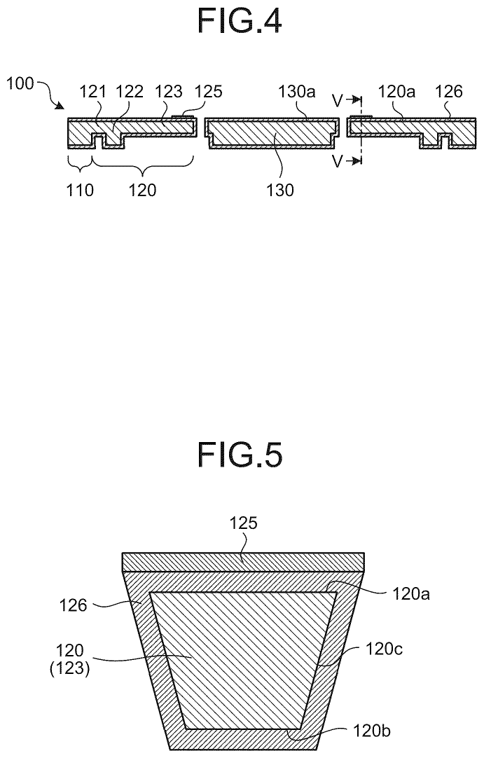

FIG. 2 is a top view illustrating a structure of the lead frame 100 according to one embodiment, and FIG. 3 is a bottom view illustrating the structure of the lead frame 100 according to one embodiment. FIG. 4 is a cross-sectional view taken along a line IV-IV in FIG. 2. In FIG. 2 to FIG. 4, the single lead frame 100 in the assembly is illustrated in an enlarged manner. In the following descriptions, a surface of the lead frame 100 that is located at the side of a semiconductor element when the semiconductor element is mounted will be referred to as an “upper surface”, a surface that is located opposite to the semiconductor element will be referred to as a “lower surface”, and a vertical direction is defined accordingly. However, the lead frame 100 may be manufactured and used in, for example, an upside-down manner and may be manufactured and used in an arbitrary posture.

The lead frame 100 includes the frame body 110, a plurality of leads 120, a die pad 130, and coupling portions 140.

The frame body 110 defines an outer circumference of the single lead frame 100 and supports the leads 120. An upper surface of the frame body 110, upper surfaces 120a of the leads 120, and an upper surface 130a of the die pad 130 are located in the same plane. Each of the leads 120 extends from the frame body 110 toward the die pad 130, and the die pad 130 is connected to the frame body 110 by the coupling portions 140. Meanwhile, when a semiconductor device is formed by using the lead frame 100, the lead frame 100 is cut at dashed lines in FIG. 2 and FIG. 3, so that the leads 120 and the coupling portions 140 are separated from the frame body 110.

The leads 120 extend from the frame body 110 toward the die pad 130 and form terminals for electrically connecting an electronic component, such as a semiconductor element, to an external component when the electronic component is mounted on the lead frame 100. At the side of the upper surface of the lead frame 100 at which the semiconductor element is mounted, plating layers 125 are formed on the leads 120. Specifically, each of the leads 120 includes a first portion 121 that is connected to the frame body 110, a second portion 122 that has a larger thickness than the first portion 121, and a third portion 123 that has a smaller thickness than the second portion 122, and the plating layer 125 is formed on an upper end surface of the third portion 123. As the plating layer 125, silver or nickel/palladium/gold (a plating layer in which a nickel layer, a palladium layer, and a gold layer are laminated in this order) may be used. When a semiconductor element is mounted on the lead frame 100, the semiconductor element that is mounted on the lead frame 100 is connected to the plating layers 125 by wire bonding on the upper surfaces 120a of the leads 120. Specifically, the upper surfaces 120a of the leads 120 serve as connection surfaces for the semiconductor element, and the plating layers 125 serve as connection portions for the semiconductor element. Further, when the semiconductor element that is mounted on the lead frame 100 is molded by sealing resin and a semiconductor device is formed, lower surfaces of the second portions 122 of the leads 120 are exposed from the sealing resin and form terminals of the semiconductor device.

The die pad 130 is a plate-shaped region that is formed in the center of the lead frame 100, and connected to the frame body 110 by, for example, the four coupling portions 140. The semiconductor element is mounted on the upper surface 130a of the die pad 130. Specifically, the upper surface 130a of the die pad 130 serves as a mounting surface for the semiconductor element. A stepped portion is formed on an outer circumference of a lower surface of the die pad 130.

In the present embodiment, as illustrated in FIG. 4, a plating film 126 is formed on a surface of the lead frame 100. The plating film 126 covers the frame body 110, the leads 120, the die pad, 130 and the coupling portions 140 (see FIG. 2 and FIG. 3). As a material of the plating film 126, for example, copper, nickel, or the like may be used.

Shapes of the lead 120 and the plating film 126 will be described in detail below with reference to FIG. 5. FIG. 5 is a diagram illustrating a cross-section perpendicular to a longitudinal direction of the lead 120. FIG. 5 illustrates a cross section taken along a line V-V in FIG. 4.

The plating film 126 covers all of the surfaces including the upper surface 120a, a lower surface 120b, and side surfaces 120c of the lead 120. In the plating film 126, a film thickness of a portion that covers the upper surface 120a of the lead 120 and a film thickness of a portion that covers the lower surface 120b of the lead 120 are the same, and is set to, for example, about 1 to 5 micrometers (μm). Further, in the plating film 126, a film thickness of a portion that covers the side surfaces 120c of the lead 120 is set to, for example, 0.5 to 2.5 μm. Here, in the plating film 126, the film thickness of the portion that covers the side surfaces 120c may be smaller than the film thicknesses of the portions that cover the upper surface 120a and the lower surface 120b.

In this manner, in the present embodiment, the entire circumference of the lead 120 is covered by the plating film 126. With this configuration, it is possible to increase strength of the lead 120 without forming a reinforcing protrusion on the side surfaces 120c of the lead 120, and it is possible to fully secure a distance between the adjacent leads 120. As a result, it is possible to prevent occurrence of a short circuit defect between the adjacent leads 120 and prevent deformation of the leads 120.

The lead 120 has a tapered shape in which, in the cross section perpendicular to the longitudinal direction of the lead 120, a width of the upper surface 120a is larger than a width of the lower surface 120b, and a width of the portion of the plating film 126 that convers the upper surface 120a is larger than a width of the portion of the plating film 126 that covers the lower surface 120b. In this manner, by covering the upper surface 120a of the lead 120 by the plating film 126 with a relatively large width, it is possible to substantially increase the width of the upper surface 120a of the lead 120 that serves as the connection surface for the semiconductor element by the width of the plating film 126. As a result, it is possible to increase a surface area of the plating layer 125 that is formed on the upper surface 120a of the lead 120, so that it is possible to improve reliability of connection between the semiconductor element and the plating layer 125 that are connected by wire bonding.

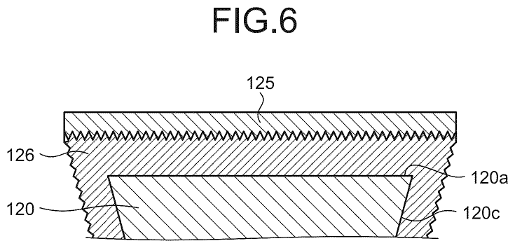

FIG. 6 is a diagram illustrating a specific example of a surface of the plating film 126. The plating film 126 is formed by, for example, roughening copper plating. Therefore, as illustrated in FIG. 6, the surface of the plating film 126 is a roughened surface in which surface roughness is increased. Specifically, surface roughness of the surface of the plating film 126 is larger than surface roughness of all of the surfaces including the upper surface 120a, the lower surface 120b, and the side surfaces 120c of the lead 120. Therefore, when the semiconductor element that is mounted on the lead frame 100 is molded by sealing resin, roughened portions of the plating film 126 are filled with the sealing resin, so that it is possible to improve adhesiveness between the lead 120 and the sealing resin via the plating film 126 due to the anchor effect.

Furthermore, in the plating film 126, surface roughness of the portion that covers the upper surface 120a of the lead 120 is larger than surface roughness of the portion that covers the lower surface 120b of the lead 120. Therefore, when the semiconductor element that is mounted on the lead frame 100 is molded by the sealing resin, it is possible to improve adhesiveness between the upper surface 120a of the lead 120, which has a larger contact area with the sealing resin as compared to the lower surface 120b of the lead 120, and the sealing resin. Meanwhile, in the plating film 126, it may be possible to increase the surface roughness of the portion that covers the upper surface 120a of the lead 120 as compared to the surface roughness of the portion that covers the side surfaces 120c of the lead 120.

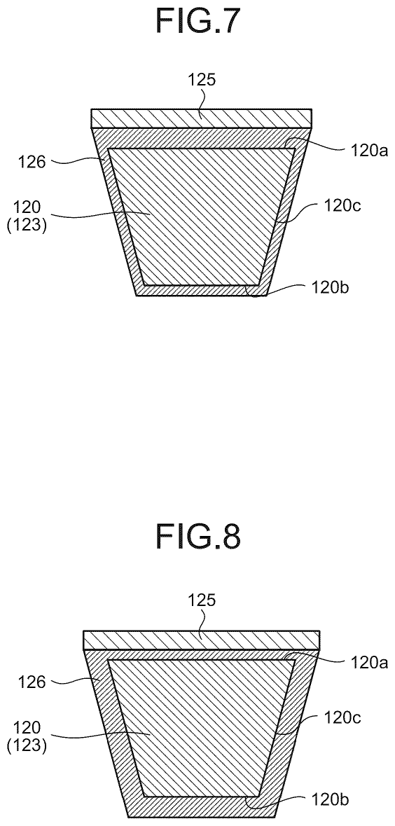

Meanwhile, in the plating film 126, the film thickness of the portion that covers the upper surface 120a of the lead 120 and the film thickness of the portion that covers the lower surface 120b of the lead 120 need not always be the same. FIG. 7 and FIG. 8 are diagrams illustrating specific examples of the film thickness of the plating film 126. For example, as illustrated in FIG. 7, in the plating film 126, the film thickness of the portion that covers the lower surface 120b and the side surfaces 120c of the lead 120 may be smaller than the film thickness of the portion that covers the upper surface 120a of the lead 120. In this case, the film thickness of the portion that covers the upper surface 120a of the lead 120 may be set to, for example, about 1 to 5 μm, and the film thickness of the portion that covers the lower surface 120b and the side surfaces 120c of the lead 120 may be set to, for example, 0.5 to 2.5 μm. Furthermore, as illustrated in FIG. 8 for example, in the plating film 126, the film thickness of the portion that covers the upper surface 120a of the lead 120 may be smaller than the film thickness of the portion that covers the lower surface 120b and the side surfaces 120c of the lead 120. In this case, the film thickness of the portion that covers the upper surface 120a of the lead 120 may be set to, for example, 0.5 to 2.5 μm, and the film thickness of the portion that covers the lower surface 120b and the side surfaces 120c of the lead 120 may be set to, for example, about 1 to 5 μm. By locally reducing the film thickness of the plating film 126 that covers the surface of the lead 120, it is possible to prevent an increase in the thickness of the lead 120 including the film thickness of the plating film 126, and it is possible improve the strength of the lead 120.

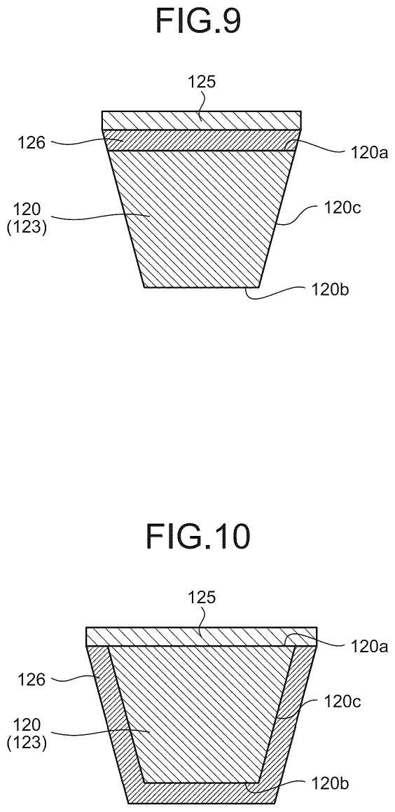

Moreover, the plating film 126 may partly cover the surface of the lead 120. FIG. 9 and FIG. 10 are diagrams illustrating specific examples of a coating range of the plating film 126. For example, as illustrated in FIG. 9, the plating film 126 may be formed on the upper surface 120a of the lead 120 and cover only the upper surface 120a of the lead 120. In this case, the lower surface 120b and the side surfaces 120c of the lead 120 are exposed from the plating film 126. Furthermore, as illustrated in FIG. 10 for example, the plating film 126 may be formed on the lower surface 120b and the side surfaces 120c of the lead 120 and cover only the lower surface 120b and the side surfaces 120c of the lead 120. In this case, the upper surface 120a of the lead 120 is exposed from the plating film 126. By partly covering the surface of the lead 120, it is possible to prevent an increase in the thickness of the lead 120 including the film thickness of the plating film 126, and it is possible improve the strength of the lead 120.

Moreover, the plating film 126 covers all of the surfaces the die pad 130 in addition to all of the surfaces of the lead 120. Specifically, the plating film 126 covers all of the surfaces of the die pad 130 including the upper surface 130a that serves as the mounting surface for the semiconductor element, the lower surface, and side surfaces. A film thickness or surface roughness of the plating film 126 that covers the surface of the die pad 130 are the same as the film thickness or the surface roughness of the plating film 126 that covers the surface of the lead 120. By covering the entire circumference of the die pad 130 by the plating film 126, it is possible to improve strength of the die pad 130. As a result, it is possible to prevent deformation of the die pad 130.

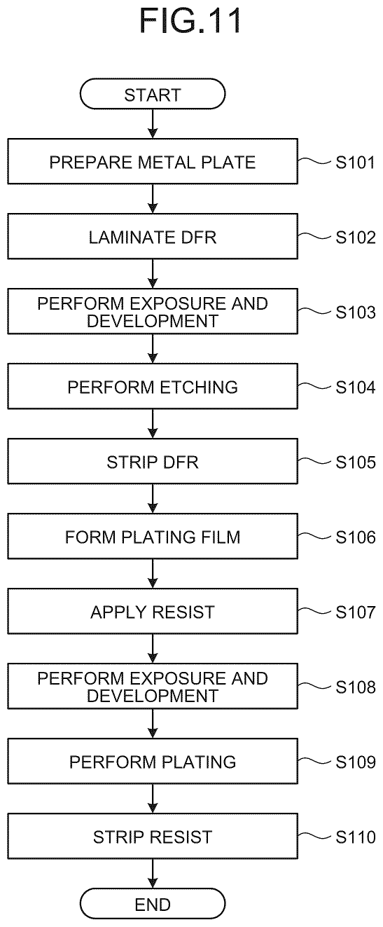

A method of manufacturing the lead frame 100 that is configured as described above will be described below with a specific example with reference to FIG. 11. FIG. 11 is a flowchart illustrating a method of manufacturing the lead frame 100 according to one embodiment. Processes described below are performed on, for example, the assembly of the lead frames 100 as illustrated in FIG. 1; however, in the following, each of the processes will be described in detail below by focusing on the single lead frame 100.

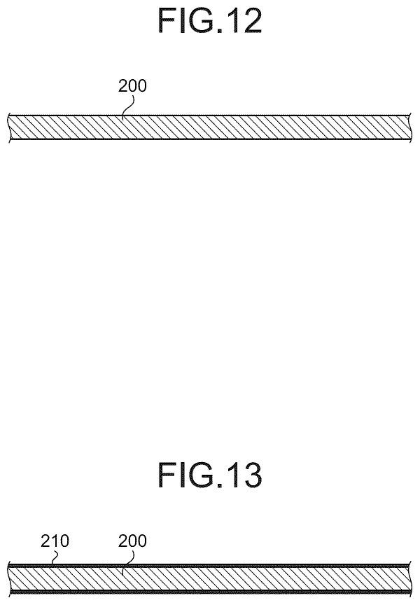

First, as illustrated in FIG. 12 for example, a metal plate 200 that serves as a base material of the lead frame 100 is prepared (Step S101). FIG. 12 is a diagram illustrating a specific example of a structure of the metal plate 200. As a material of the metal plate 200, metal, such as copper or a copper alloy, may be used, for example. A thickness of the metal plate 200 may be set to, for example, about 0.1 to 0.25 millimeters (mm).

Further, a Dry Film Resist (DFR) that is etching resist is laminated on a surface of the metal plate 200 (Step S102). Specifically, as illustrated in FIG. 13 for example, a DFR 210 is laminated on an upper surface and a lower surface of the metal plate 200. FIG. 13 is a diagram illustrating a specific example of a DFR lamination process.

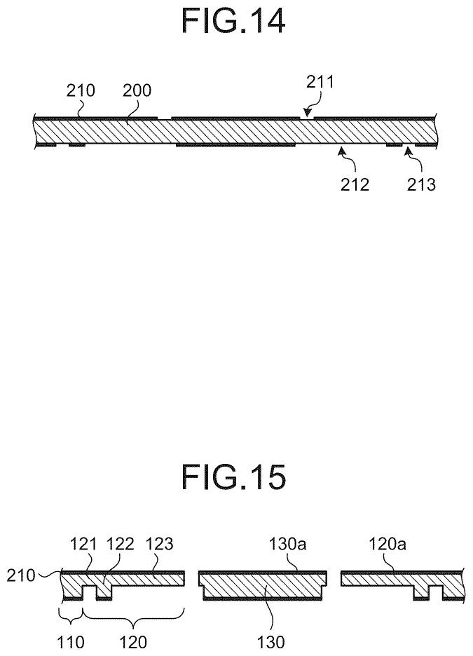

After the DFR 210 is laminated, exposure and development are performed (Step S103), so that the DFR 210 with predetermined opening portions is formed. Specifically, as illustrated in FIG. 14 for example, exposure and development are performed on the DFR 210 at the sides of the upper surface and the lower surface of the metal plate 200, so that the DFR 210 with opening portions 211 to 213 is formed. FIG. 14 is a diagram illustrating a specific example of an exposure and development process. At the side of the upper surface of the metal plate 200, the opening portion 211 is formed in a portion in which through-etching is performed. Furthermore, at the side of the lower surface of the metal plate 200, the opening portion 212 is formed in a portion in which through-etching and half-etching are performed. Moreover, at the side of the lower surface of the metal plate 200, the opening portion 213 is formed in a portion in which half-etching is performed.

After the DFR 210 with the opening portions 211 to 213 is formed at each of the sides of the upper surface and the lower surface of the metal plate 200, the metal plate 200 is immersed in an etching liquid (Step S104). Specifically, for example, the metal plate 200 is immersed in an etching liquid, such as sulfuric acid-hydrogen peroxide or persulfate, so that the surface of the metal plate 200 exposed from the opening portions 211 to 213 of the DFR 210 is dissolved and the shape of the lead frame 100 is formed.

Specifically, as illustrated in FIG. 15 for example, in a region in which the upper surface and the lower surface are exposed from the opening portion 211 and the opening portion 212, the upper surface and the lower surface of the metal plate 200 are dissolved and the lead 120 and the die pad 130 are separated from each other. Further, in a region in which only the lower surface is exposed from the opening portion 212 and the opening portion 213, the lower surface of the metal plate 200 is dissolved and subjected to half-etching, so that the first portion 121 and the third portion 123 of the lead 120 are formed. FIG. 15 is a diagram illustrating a specific example of an etching process.

In this manner, by the etching, the lead 120 and the die pad 130 are separated from each other and the first portion 121 and the third portion 123 in the lead 120 are formed. Furthermore, in the lead 120, the second portion 122 that is not subjected to etching and that has a lager thickness than the first portion 121 and the third portion 123 remain between the first portion 121 and the third portion 123.

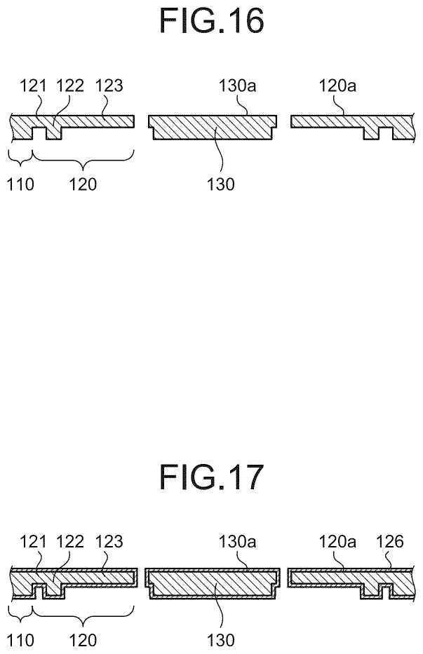

After the etching is completed, the DFR 210 is stripped by using, for example, an amine-based or non-amine-based stripping solution (Step S105), so that the lead frame 100 that includes the lead 120 and the die pad 130 is obtained. Specifically, as illustrated in FIG. 16 for example, the lead frame 100 in which the lead 120 and the die pad 130 are separated from each other is obtained. FIG. 16 is a diagram illustrating a specific example of a DER stripping process.

After the lead frame 100 is formed, the plating film 126 is formed on the entire surface of the lead frame 100 by roughening copper plating (Step S106). Specifically, as illustrated in FIG. 17 for example, the plating film 126 that covers the frame body 110, the leads 120, the die pad 130, and the coupling portions 140 is formed by roughening copper plating (see FIG. 2 and FIG. 3). FIG. 17 is a diagram illustrating a specific example of a plating film formation process. The plating film 126 is formed so as to cover all of the surfaces including the upper surfaces 120a, the lower surfaces 120b, and the side surfaces 120c of the lead 120. At this time, by appropriately adjusting a composition and an electrolytic copper plating condition of a copper sulfate plating solution that is used for the roughening copper plating, it may be possible to form the plating film 126 that has different surface roughness or a film thickness between the upper surface 120a and the lower surface of the lead 120.

Specifically, in the plating film 126, the surface roughness of the portion that covers the upper surface 120a of the lead 120 may be larger than the surface roughness of the portion that covers the lower surface 120b of the lead 120. In this case, for example, a surface area ratio Sratio that represents the surface roughness of the portion that covers the upper surface 120a of the lead 120 may be set to, for example, about 1.5 to 2.0, and a surface area ratio Sratio of the surface roughness of the portion that covers the lower surface 120b of the lead 120 may be set to, for example, about 1.1 to 1.5. Assuming that a certain region has an area S0 in a planar view and has an actual surface area S, the surface area ratio Sratio represents a ratio of the actual surface area S to the area S0 and is represented by “S/S0”. With an increase in the surface area ratio Sratio, the surface roughness increases. Meanwhile, a surface of the portion in the plating film 126 that covers the lower surface 120b of the lead 120 may be formed as a smooth surface by setting the surface area ratio Sratio of the portion that covers the lower surface 120b of the lead 120 to be smaller than 1.1.

Furthermore, in the plating film 126, the film thickness of the portion that covers the lower surface 120b of the lead 120 may be smaller than the film thickness of the portion that covers the upper surface 120a of the lead 120. In this case, the film thickness of the portion that covers the upper surface 120a of the lead 120 may be set to, for example, about 1 to 5 μm, and the film thickness of the portion that covers the lower surface 120b of the lead 120 may be set to, for example, 0.5 to 2.5 μm. Moreover, in the plating film 126, the film thickness of the portion that covers the upper surface 120a of the lead 120 may be smaller than the film thickness of the portion that covers the lower surface 120b of the lead 120. In this case, the film thickness of the portion that covers the upper surface 120a of the lead 120 may be set to, for example, 0.5 to 2.5 μm, and the film thickness of the portion that covers the lower surface 120b of the lead 120 may be set to, for example, about 1 to 5 μm.

Examples of the composition of the copper sulfate plating solution that is used for the roughening copper plating include the followings.
copper sulfate: 200 g/L
sulfuric acid: 100 g/L
chlorine: 50 ppm
polymer (inhibitor): 20 mL/L
brightener (accelerator): 2 mL/L
leveler: 10 mL/L

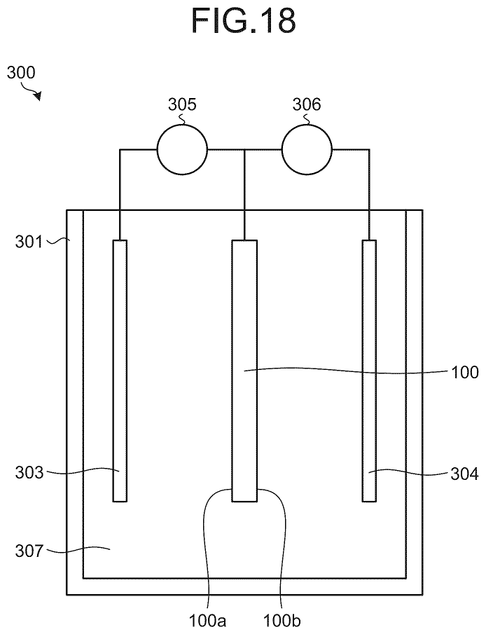

The roughening copper plating using the copper sulfate plating solution as described above is performed by using, for example, a plating device illustrated in FIG. 18 under a predetermined electrolytic copper plating condition. FIG. 18 is a diagram illustrating a configuration example of the plating device that performs the roughening copper plating. A plating device 300 illustrated in FIG. 18 includes a plating tank 301, a pair of electrodes 303 and 304, a polarity reversal power supply 305, and a direct-current power supply 306.

The plating tank 301 stores therein a copper sulfate plating solution 307. A composition of the copper sulfate plating solution 307 that is stored in the plating tank 301 is, for example, as described above. The formed lead frame 100 is set in the plating tank 301 when being subjected to the roughening copper plating.

The electrode 303 is arranged so as to face one principal plane 100a of the lead frame 100 in the plating tank 301. The one principal plane 100a of the lead frame 100 is located at a side of one of the upper surface 120a and the lower surface 120b of the lead 120. The electrode 304 is arranged so as to face another principal plane 100b of the lead frame 100 in the plating tank 301. The other principal plane 100b of the lead frame 100 is located at the other one of the upper surface 120a and the lower surface 120b of the lead 120.

The polarity reversal power supply 305 is connected to the lead frame 100 and the electrode 303, and supplies a pulse current, for which a polarity is periodically reversed, to the lead frame 100 and the electrode 303.

The direct-current power supply 306 is connected to the lead frame 100 and the electrode 304, and supplies a constant current to the lead frame 100 and the electrode 304.

The electrolytic copper plating condition that is used in the plating device 300 as described above may be adjusted arbitrarily in accordance with the surface roughness or the film thickness of the plating film 126 to be formed. For example, a magnitude of the pulse current that is supplied from the polarity reversal power supply 305, a supply time at each of the positive side and the negative side of the pulse current, and the like are adjusted arbitrarily in accordance with the surface roughness or the film thickness of the plating film 126 to be formed. Furthermore, for example, a magnitude of the current that is supplied from the direct-current power supply 306 is adjusted arbitrarily in accordance with the surface roughness or the film thickness of the plating film 126 to be formed. By adjusting the composition of the copper sulfate plating solution and the electrolytic copper plating condition that is used for the roughening copper plating, it is possible to form the plating film 126 with different surface roughness or a different film thickness between the upper surface 120a and the lower surface 120b of the lead 120.

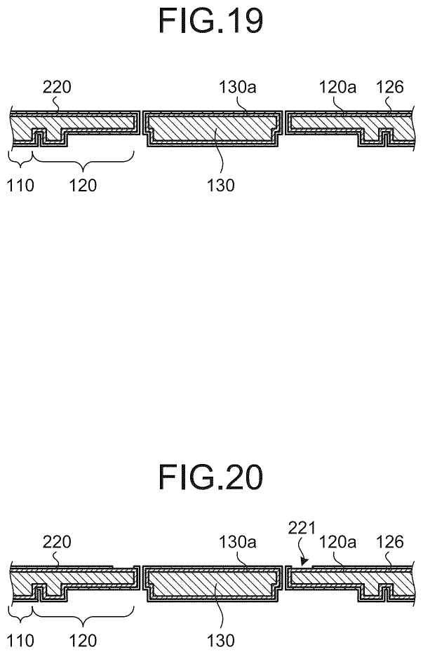

After the plating film 126 is formed on the surface of the lead frame 100, a resist for performing plating is applied to the upper surface 120a of the lead 120 (Step S107). Specifically, as illustrated in FIG. 19 for example, a resist 220 is applied to the entire surface of the frame body 110, the leads 120, the coupling portions 140, and the die pad 130. The resist 220 may be formed by electrodeposition of an electrodeposition resist. FIG. 19 is a diagram illustrating a specific example of a resist application process. Meanwhile, in reality, the resist 220 is applied to the entire surface of the frame body 110, the leads 120, the coupling portions 140, and the die pad 130 via the plating film 126; however, in the following, explanation of the plating film 126 will be omitted appropriately for the sake of convenience.

After the resist 220 is applied, exposure and development are performed (Step S108), so that the resist 220 with a predetermined opening portion is formed. Specifically, as illustrated in FIG. 20 for example, exposure and development are performed on the resist 220 at the side of the upper surface of the lead frame 100, so that the resist 220 with an opening portion 221 is formed. FIG. 20 is a diagram illustrating a specific example of an exposure and development process. In the opening portion 221, a part (wire bonding portion) of the upper surface 120a of the lead 120 that serves as the connection surface for the semiconductor element is exposed.

The lead frame 100 in which a part of the upper surface 120a of the lead 120 is exposed from the opening portion 221 of the resist 220 is immersed in, for example, a plating solution for silver plating and subjected to plating (Step S109). Specifically the lead frame 100 is immersed in, for example, a plating solution that contains silver cyanide and potassium cyanide as main components, and subjected to electrolytic plating, so that the plating layer 125 is formed on the upper surface 120a of the lead 120.

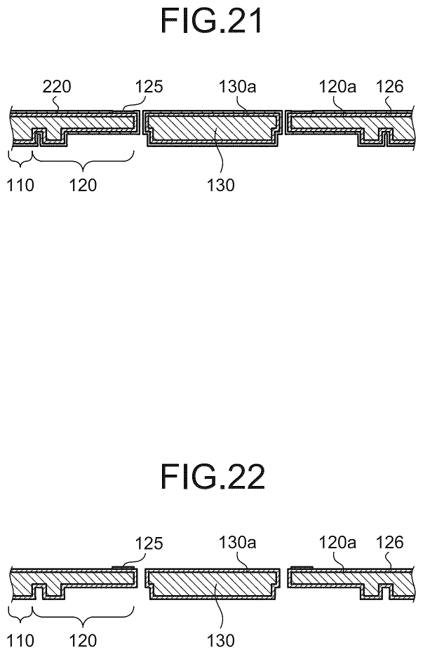

More specifically, as illustrated in FIG. 21 for example, silver that is contained in the plating solution is precipitated in the part of the upper surface 120a of the lead 120 that is exposed from the opening portion 221 of the resist 220, and the plating layer 125 with a thickness of, for example, 0.1 to 10 μm is formed. FIG. 21 is a diagram illustrating a specific example of a plating process.

After formation of the plating layer 125, the resist 220 is stripped by using, for example, a stripping solution (Step S110), and the lead frame 100 is completed. Specifically, as illustrated in FIG. 22 for example, the plating layer 125 is formed on the upper surfaces 120a of the leads 120, and the lead frame 100 in which the frame body 110, the leads 120, the coupling portions 140, the die pad 130 are covered by the plating film 126 is completed. FIG. 22 is a diagram illustrating a specific example of a resist stripping process.

In this manner, after the etching for separating the lead 120 and the die pad 130, the plating film 126 that covers all of the surfaces of the lead 120 is formed by the roughening copper plating. Therefore, it is possible to increase the strength of the lead 120 without forming a reinforcing protrusion on the side surfaces 120c of the lead 120, and it is possible to fully secure a distance between the adjacent leads 120. As a result, it is possible to prevent occurrence of a short circuit defect between the adjacent leads 120 and prevent deformation of the leads 120. Furthermore, the plating film 126 covers all of the surfaces of the die pad 130 in addition to all of the surfaces of the lead 120, so that it is possible to increase the strength of the die pad 130 and prevent deformation of the die pad 130.

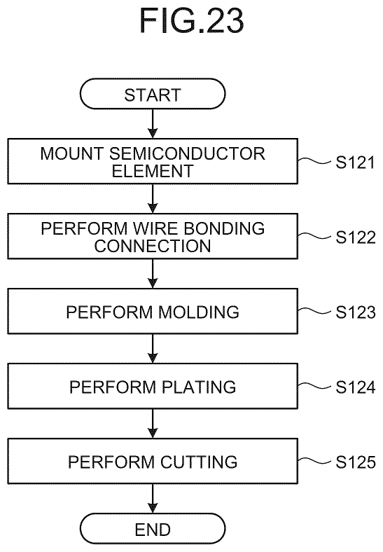

A process of manufacturing a semiconductor device by mounting a semiconductor element on the lead frame 100 will be described below with a specific example with reference to FIG. 23. FIG. 23 is a flowchart illustrating a method of manufacturing a semiconductor device according to one embodiment.

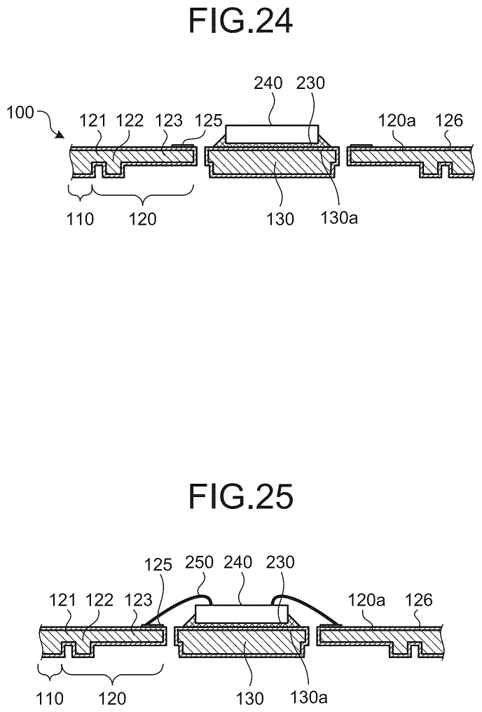

First, a semiconductor element is mounted on the die pad 130 of the lead frame 100 (Step S121). Specifically, as illustrated in FIG. 24 for example, a semiconductor element 240 is bonded to the upper surface 130a of the die pad 130 by a bonding material 230, such as a solder or a die attach paste. FIG. 24 is a diagram illustrating a specific example of a semiconductor element mounting process.

After the semiconductor element 240 is bonded to the die pad 130, the semiconductor element 240 and the leads 120 are connected to each other by wire bonding (Step S122). Specifically, as illustrated in FIG. 25 for example, electrodes of the semiconductor element 240 are electrically connected to the plating layer 125 on the upper surfaces 120a of the leads 120 by a wire 250. FIG. 25 is a diagram illustrating a specific example of a wire bonding connection process.

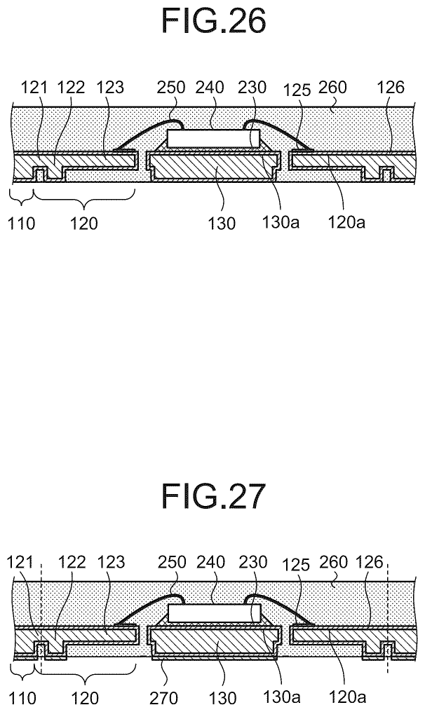

Further, molding is performed to seal the semiconductor element 240 mounted on the lead frame 100 by sealing resin (Step S123). Specifically, the lead frame 100 on which the semiconductor element 240 is mounted is accommodated in a mold, and fluidized sealing resin is injected in the mold. Further, the sealing resin is heated to predetermined temperature so as to be cured, so that a space around the semiconductor element 240 is filled with sealing resin 260 as illustrated in FIG. 26 for example, and the semiconductor element 240 that is mounted on the lead frame 100 is sealed. At this time, because the surface of the plating film 126 that covers all of the surfaces of the leads 120 are a roughened surface, the roughened portions of the plating film 126 are filled with the sealing resin 260, so that it is possible to improve adhesiveness between the leads 120 and the sealing resin 260 via the plating film 126 due to the anchor effect. With this configuration, it is possible to reduce the possibility that the leads 120 are separated from the sealing resin 260. FIG. 26 is a diagram illustrating a specific example of a molding process.

At a stage at which the semiconductor element 240 that is mounted on the lead frame 100 is sealed by the sealing resin 260, the lower surface of the frame body 110, the lower surfaces of the second portions 122 of the leads 120, and the lower surface of the die pad 130 are exposed from a lower surface of the sealing resin 260. Therefore, plating is performed to cover the exposed surfaces (Step S124). Specifically, as illustrated in FIG. 27 for example, electrolytic plating with tin, solder, or the like is performed, so that an exterior plating layer 270 is formed on the lower surface of the frame body 110, the lower surfaces of the second portions 122 of the leads 120, and the lower surface of the die pad 130 that are exposed from the sealing resin 260. FIG. 27 is a diagram illustrating a specific example of a plating process.

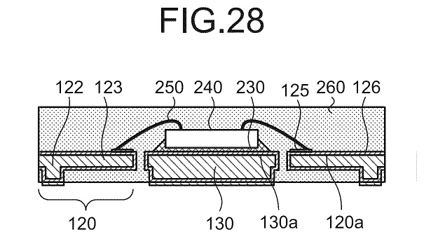

After the exterior plating layer 270 is formed on an exposed surface of the lead frame 100, which is exposed from the sealing resin 260, the sealing resin 260 is cut and the leads 120 and the coupling portions 140 are cut from the frame body 110 in dashed line portions illustrated in FIG. 27 (Step S125). Accordingly, the frame body 110 is separated and removed from the lead frame 100, and, as illustrated in FIG. 28 for example, the semiconductor device that includes the leads 120, the die pad 130, the semiconductor element 240, and the sealing resin 260 is completed. FIG. 28 is a diagram illustrating a structure of the semiconductor device. In the semiconductor device illustrated in FIG. 28, the lower surfaces of the second portions 122 of the leads 120 are exposed from the lower surface of the sealing resin 260 and serve as terminals for external connection. Furthermore, the lower surface of the die pad 130 is exposed from the lower surface of the sealing resin 260.

As described above, a lead frame according to one embodiment (as one example, the lead frame 100) includes a lead (as one example, the lead 120), a connection portion (as one example, the plating layer 125), and a plating film (as one example, the plating film 126). The lead includes an upper surface (as one example, the upper surface 120a) and a lower surface (as one example, the lower surface 120b), and a width of the upper surface is larger than a width of the lower surface. The connection portion is arranged on the upper surface and serves as a connection portion for a semiconductor element. The plating film covers a surface of the lead. With this configuration, it is possible to prevent occurrence of a short circuit defect and deformation of the lead.

### Modification

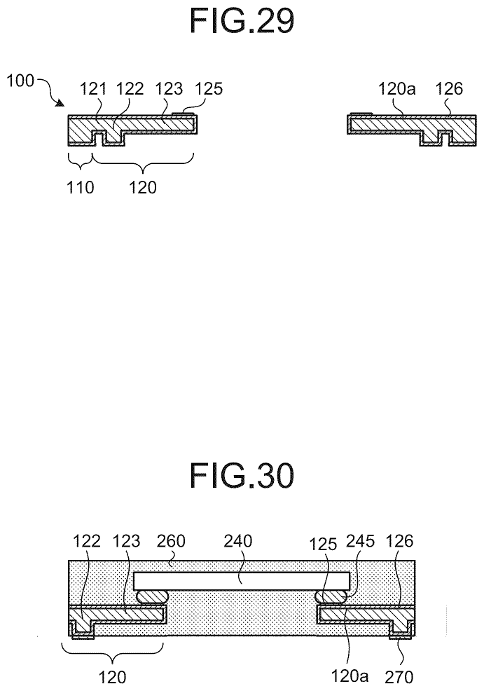

In the lead frame 100 according to one embodiment as described above, the example has been described in which a semiconductor element is mounted on the upper surface 130a of the die pad 130; however, when it is possible to mount a semiconductor element on the upper surfaces 120a of the leads 120, it may be possible to omit the die pad 130 and the coupling portions 140. Specifically, as illustrated in FIG. 29 for example, a lead frame 100 according to a modification does not include the die pad 130 and the coupling portions 140, and the upper surfaces 120a of the leads 120 serve as mounting surfaces for the semiconductor element and serves as a connection surface for the semiconductor element. FIG. 29 is a cross-sectional view of the lead frame 100 according to one modification of one embodiment. Even in the lead frame 100 according to one modification, the plating film 126 covers all of the surfaces including the upper surface 120a, the lower surface 120b and the side surfaces 120c of the lead 120.

FIG. 30 is a diagram illustrating a structure of a semiconductor device that is manufactured by using the lead frame 100 illustrated in FIG. 29. In the semiconductor device illustrated in FIG. 30, the semiconductor element 240 is connected to the upper surfaces 120a of the leads 120 in a flip chip manner. Specifically, electrodes of the semiconductor element 240 are electrically connected to the plating layer 125 on the upper surfaces 120a of the leads 120 by solder bumps 245.

According to one aspect of the lead frame disclosed in the present application, it is possible to prevent occurrence of a short circuit defect and deformation of a lead.

(Note) A lead frame manufacturing method comprising:
forming a lead from a metal plate, the lead including an upper surface and a lower surface, the upper surface having a larger width than a width of the lower surface; and
forming a plating film that covers a surface of the lead.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A lead frame comprising:
a lead that includes an upper surface and a lower surface, the upper surface having a larger width than a width of the lower surface;
a connection portion that is arranged on the upper surface and serves as a connection portion for a semiconductor element; and
a plating film that covers a surface of the lead.

2. The lead frame according to claim 1, wherein, in the plating film, a film thickness of a portion that covers the lower surface is smaller than a film thickness of a portion that covers the upper surface.

3. The lead frame according to claim 1, wherein, in the plating film, a film thickness of a portion that covers the upper surface is smaller than a film thickness of a portion that covers the lower surface.

4. The lead frame according to claim 1, wherein
the lead includes a side surface between the upper surface and the lower surface, and
in the plating film, a film thickness of a portion that covers the side surface is smaller than a film thickness of a portion that covers one of the upper surface and the lower surface.

5. The lead frame according to claim 1, wherein
a surface of the plating film is a roughened surface, and
surface roughness of the surface of the plating film is larger than surface roughness of the surface of the lead.

6. The lead frame according to claim 1, wherein, in the plating film, surface roughness of a portion that covers the upper surface is larger than surface roughness of a portion that covers the lower surface.

7. The lead frame according to claim 1, wherein the connection portion is arranged on the plating film that covers the upper surface and is formed of a plating layer of a different material from the plating film.

8. The lead frame according to claim 1, wherein the lead has a tapered shape in which a width of the upper surface is larger than a width of the lower surface in a cross section perpendicular to a longitudinal direction of the lead.

9. The lead frame according to claim 1, further comprising:
a die pad that includes a mounting surface for the semiconductor element, wherein
the plating film covers a surface of the die pad.

10. A semiconductor device comprising:
a lead frame;
a semiconductor element that is mounted on the lead frame; and
sealing resin that seals the semiconductor element, wherein
the lead frame includes
a lead that includes an upper surface and a lower surface, the upper surface having a larger width than a width of the lower surface;
a connection portion that is arranged on the upper surface and serves as a connection portion for the semiconductor element; and
a plating film that covers a surface of the lead.
